(19) United States
(12) Patent Application Publication
(10) Pub. No.: US 2026/0131483 A1
(43) Pub. Date: May 14, 2026

(54) CLAMPING JAW APPARATUS

(71) Applicant: Gyrobot Technology (Suzhou) Co., Ltd., Suzhou (CN)

(72) Inventors: Weifeng XU, Suzhou (CN); Weiqiang CHEN, Suzhou (CN); Zhenyi ZHANG, Suzhou (CN)

(73) Assignee: Gyrobot Technology (Suzhou) Co., Ltd., Suzhou (CN)

(21) Appl. No.: 19/383,460

(22) Filed: Nov. 7, 2025

(30) Foreign Application Priority Data
Nov. 13, 2024 (CN) 202411618179.7

(51) Int. Cl. B25J 15/00; B25J 19/02

(52) U.S. Cl. CPC B25J 15/0033; B25J 19/021

(57) ABSTRACT

The present disclosure provides a clamping jaw apparatus for clamping a magazine body. The magazine body includes a top plate provided with at least two lifting members, and the lifting member includes a recessed structure. The clamping jaw apparatus includes at least two clamping jaw units; the clamping jaw unit includes a protruding structure, and the protruding structure cooperates with the recessed structure. The clamping jaw unit moves in a direction proximal to the lifting member, so that the protruding structure and the recessed structure engage and abut to form a snap-fit structure. In the solutions, the protruding structure on the clamping jaw unit and the recessed structure of the lifting member on the top plate of the magazine body are designed to complement and cooperate with each other, and thus the two are snap-fitted to form the snap-fit structure, realizing the stable clamping of the magazine body.

### CROSS-REFERENCE TO RELATED APPLICATIONS

The present application claims priority to Chinese Patent Application No. 202411618179.7, filed on November 13, 2024. The disclosure of the above-referenced application is hereby incorporated by reference in its entirety.

### BACKGROUND

A wafer is a basic raw material for manufacturing a semiconductor device. A very high-purity semiconductor is manufactured into a wafer through processes such as crystal pulling and slicing. The wafer is subjected to a series of semiconductor manufacturing processes to form a very small circuit structure, and then is cut, packaged, and tested to form an IC chip, which is widely applied to various electronic devices.

In a semiconductor process, the IC chip needs to undergo a plurality of processing stages. To ensure the safety of the IC chip in the processing stages, the IC chip is stored in a magazine during storage and transportation, thereby ensuring the stability of the IC chip during transportation.

In the processing stages, a clamping jaw is often used to grip a magazine, and the clamping jaw is driven by a manipulator to transport the magazine to a designated position. The magazine is provided with openings at two ends; the IC chip is placed inside the magazine through the openings; the clamping jaw directly clamps two side walls of the magazine that are not provided with the openings. When the clamping force of the clamping jaws is not properly controlled, if the clamping force is too large, physical damage may be caused to the metal surface of the magazine; if the clamping force is too small, the magazine may not be firmly clamped, resulting in a shift in the center of gravity and thus deflection of the magazine. As a result, the IC chip may slide out from the opening, and in severe cases, the magazine directly falls off, resulting in damage to both the magazine and the IC chip.

Therefore, how to provide a clamping jaw with strong stability is a technical problem that needs to be urgently resolved by a person skilled in the art.

### SUMMARY

To resolve the problems in the prior art, the present disclosure provides a clamping jaw apparatus to resolve one or more technical problems in the prior art.

The present disclosure relates to the field of object handling technologies, and in particular, to a clamping jaw apparatus.

Provided is a clamping jaw apparatus for clamping a magazine body. The magazine body includes a top plate provided with at least two lifting members, and the lifting member includes a recessed structure. The clamping jaw apparatus includes:

at least two clamping jaw units, where the clamping jaw unit includes a protruding structure, and the protruding structure cooperates with the recessed structure;

the clamping jaw unit moves in a direction proximal to the lifting member, so that the protruding structure and the recessed structure engage and abut to form a snap-fit structure, or moves in a direction distal to the lifting member, so that the protruding structure and the recessed structure are separated to disconnect the snap-fit structure.

The protruding structure on the clamping jaw unit and the recessed structure of the lifting member on the top plate of the magazine body are designed to complement and cooperate with each other, and thus the two are snap-fitted to form the snap-fit structure, realizing the stable clamping of the magazine body, thereby protecting an object in the magazine body from damage during transportation while avoiding the problem that the magazine body is damaged or the object slides out from the magazine body due to an improper clamping force.

Preferably, the clamping jaw apparatus further includes a main controller.

The protruding structure includes a main body, a pressing structure, and a transmission structure and a microswitch that are disposed inside the main body, a notch is formed in one side of the main body, the pressing structure cooperates with the notch, and the pressing structure is connected to the transmission structure.

In a first state, the pressing structure moves from the notch to a pressing position in a direction distal to the main body, and the pressing position is located on one side of the recessed structure 1010.

In a second state, the protruding structure moves toward the recessed structure, so that the pressing structure abuts against the recessed structure; the pressing structure moves to the notch in a direction proximal to the main body and complements the notch to form a whole, so that the protruding structure and the recessed structure engage and abut to form the snap-fit structure. When the pressing structure cooperates with the notch to form a whole, the pressing structure applies an external force onto the microswitch through the transmission structure, and the microswitch transmits a locking signal to the main controller after being triggered, the locking signal being used for indicating that the clamping jaw apparatus and the magazine body are clamped.

In the first state, i.e., the initial state, the pressing structure is not embedded in the main body and naturally extends outside the main body. In the second state, i.e., under the clamping action, the pressing structure first engages and contacts the recessed structure and is then pushed back into the notch under the action of an external force to complement and cooperate with the notch to form a whole; then the protruding structure and the recessed structure engage and abut to form the snap-fit structure, so that the clamping jaw unit and the lifting member are firmly clamped, thereby improving the stability of the clamping jaw apparatus.

Preferably, the clamping jaw apparatus further includes a sliding mechanism, and the sliding mechanism includes a sliding rail and a sliding stage disposed on the sliding rail.

The clamping jaw unit is connected to the sliding stage and moves on the sliding rail through the sliding stage in the direction proximal to the lifting member or the direction distal to the lifting member.

The arrangement of the sliding mechanism enables the two clamping jaw units to move proximal to or distal to each other, so that the protruding structure and the recessed structure engage to form the snap-fit structure, or the protruding structure and the recessed structure are separated and disconnected.

Preferably, the clamping jaw apparatus further includes a driving mechanism. The driving mechanism is connected to one end of the clamping jaw unit distal to the protruding structure, so as to drive the clamping jaw unit to move on the sliding rail through the sliding stage.

The arrangement of the driving mechanism provides power for the movement of the clamping jaw unit, so that the clamping jaw unit moves on the sliding rail.

Preferably, the clamping jaw apparatus further includes a blocking sheet and at least one first sensing mechanism.

The first sensing mechanism is disposed below the clamping jaw unit in a height direction and includes a first optical signal transmitter and a first optical signal receiver, the first optical signal transmitter is configured to transmit an optical signal, and the first optical signal receiver is configured to receive the optical signal.

The blocking sheet is disposed at a bottom of the clamping jaw unit in the height direction, and when the protruding structure and the recessed structure engage and abut to form the snap-fit structure, the blocking sheet is located between the first optical signal transmitter and the first optical signal receiver to block the optical signal path; the first sensing mechanism transmits a termination signal to the main controller, and the main controller controls the driving mechanism to stop operation based on the termination signal.

When the protruding structure and the recessed structure engage to form the snap-fit structure, the clamping jaw unit is clamped with the lifting member, while the driving mechanism still does not stop operation and still drives the clamping jaw unit to move in a direction toward the lifting member. As a result, in a clamped state, the clamping jaw unit continuously presses against the lifting member, which easily causes damage to the clamping jaw unit and the lifting member. Therefore, the blocking sheet is used to cut off the optical signal path of the first sensing mechanism, and the first sensing mechanism transmits the termination signal to the main controller to stop the operation of the driving mechanism, thereby avoiding damage to the clamping jaw unit and the lifting member caused by the continuous movement of the clamping jaw unit.

Preferably, the clamping jaw apparatus further includes at least two second sensing mechanisms. The second sensing mechanism is disposed proximal to the clamping jaw unit and includes a second optical signal transmitter and a second optical signal receiver, the second optical signal transmitter is configured to transmit a detection signal in a direction toward the lifting member, and the second optical signal receiver is configured to receive a reflected signal formed after the detection signal is incident on the lifting member.

The second sensing mechanism transmits the reflected signal to the main controller, and the main controller determines whether an included angle between a transmission path of the detection signal and a plane on which the lifting member is located maintains a preset angle based on the reflected signal; if so, it is determined that relative positions of the lifting member and the clamping jaw unit meet a preset standard, and the clamping jaw unit is controlled to move in the direction proximal to the lifting member.

The second sensing mechanism is configured to detect whether the magazine body is located at a correct position. If the magazine body is not located at the correct position, the clamping jaw unit cannot be clamped with the lifting member. In this case, only when the relative positions of the lifting member and the clamping jaw unit meet the preset standard, the main controller controls the clamping jaw unit to move in the direction proximal to the lifting member to be clamped with the lifting member.

Preferably, the clamping jaw apparatus further includes a housing. The housing includes an accommodating cavity and a mounting opening, the driving mechanism is disposed on one side of the accommodating cavity distal to the mounting opening, the sliding mechanism is disposed on one side of the accommodating cavity proximal to the mounting opening, a part of the clamping jaw unit connected to the driving mechanism and the sliding mechanism is located in the accommodating cavity, and the other part of the clamping jaw unit passes through the mounting opening in a direction distal to the accommodating cavity and extends outside the housing.

The arrangement of the housing provides a mounting space for the driving mechanism and the sliding mechanism, which protects the safety of the mechanism and avoids damage to the internal mechanism caused by the collision between the clamping jaw apparatus and the outside when the clamping jaw apparatus performs a gripping action.

Preferably, the clamping jaw unit includes a first plate member, a second plate member, and a third plate member connected sequentially, the first plate member is connected to a drive end of the driving mechanism, a bottom end of the first plate member is connected to the sliding stage, one end of the second plate member is connected to one end of the first plate member distal to the drive end, the other end of the second plate member passes through the mounting opening in a direction distal to the accommodating cavity and extends outside the housing to be connected to the third plate member, and one end of the third plate member distal to the second plate member is provided with the protruding structure.

The first plate member and the third plate member may be disposed in parallel, which is convenient for the driving mechanism to drive the clamping jaw unit to move. The arrangement of the second plate member adapts to a drop between the clamping jaw apparatus and the magazine body, thereby improving the adaptability of the clamping jaw apparatus.

Preferably, the magazine body includes at least one opening, and an object is placed in the magazine body through the opening.

The clamping jaw apparatus further includes at least one shielding mechanism, the shielding mechanism is disposed on an outer side wall of the housing, and when the protruding structure and the recessed structure engage and abut, the shielding mechanism moves to the opening to abut against an end surface of the magazine body that is provided with the opening, so as to prevent the object from falling off the magazine body through the opening.

When the clamping jaw apparatus clamps the magazine body, due to the existence of the opening of the magazine body, if the magazine body is interfered with an external acting force, the magazine body may shake and vibrate, causing the object in the magazine body to fall out from the opening. In this case, the shielding mechanism blocks the opening side of the magazine body and is in close contact with the magazine body structure, which can prevent the object from falling out through the opening and thus ensure the safety of the object stored in the magazine body.

Preferably, the shielding mechanism includes a moving rod member, a shielding member, and a movable connecting member, one end of the moving rod member is connected to the housing, and the other end of the moving rod member is connected to the shielding member through the movable connecting member; the movable connecting member is configured to alleviate a reaction force applied by the magazine body onto the shielding member when the shielding member abuts against the magazine body.

When a shape of the magazine body conforms to a preset shape, the shielding member abuts against the end surface of the magazine body that is provided with the opening, the movable connecting member is in a natural state, and a first preset angle is maintained between the moving rod member and the shielding member.

When the shape of the magazine body does not conform to the preset shape, the shielding member abuts against the end surface of the magazine body that is provided with the opening, the movable connecting member is in an expanded state, and a second preset angle is maintained between the moving rod member and the shielding member. The second preset angle is greater than the first preset angle.

Different types of magazine bodies have different sizes. For the magazine body with smaller dimensions and conforming to the preset shape, the shielding member can just abut against the end surface of the magazine body that is provided with the opening when moving to the opening. For the magazine body with slightly larger dimensions and not conforming to the preset shape, the shielding member is forced open by the end surface of the magazine body that is provided with the opening when moving to the opening, and the movable connecting member is in an expanded state, so as to alleviate the reaction force applied by the magazine body onto the shielding member when the shielding member abuts against the magazine body, thereby avoiding damage to the shielding member. This design is applicable to a plurality of types of magazine bodies.

According to the embodiments provided in the present disclosure, the following technical effects are disclosed:

The present disclosure provides a clamping jaw apparatus for clamping a magazine body. The magazine body includes a top plate provided with at least two lifting members, and the lifting member includes a recessed structure. The clamping jaw apparatus includes at least two clamping jaw units; the clamping jaw unit includes a protruding structure, and the protruding structure complements the recessed structure. The clamping jaw unit moves in a direction proximal to the lifting member, so that the protruding structure and the recessed structure engage and abut to form a snap-fit structure. In the solutions, the protruding structure on the clamping jaw unit and the recessed structure of the lifting member on the top plate of the magazine body are designed to complement and cooperate with each other, and thus the two are snap-fitted to form the snap-fit structure, realizing the stable clamping of the magazine body, thereby protecting an object in the magazine body from damage during transportation while avoiding the problem that the magazine body is damaged or the object slides out from the magazine body due to an improper clamping force.

### BRIEF DESCRIPTION OF DRAWINGS

To describe the technical solutions in embodiments of the present disclosure or in the prior art more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is an overall schematic diagram of a clamping jaw apparatus according to an embodiment of the present disclosure;

FIG. 2 is a schematic diagram of a protruding structure and a recessed structure according to an embodiment of the present disclosure;

FIG. 3 is a schematic diagram of positions of a clamping jaw unit and a lifting member in a first state according to an embodiment of the present disclosure;

FIG. 4 is a schematic diagram of positions of a clamping jaw unit and a lifting member in a second state according to an embodiment of the present disclosure;

FIG. 5 is a schematic side sectional diagram of an interior of a housing of a clamping jaw apparatus according to an embodiment of the present disclosure; and

FIG. 6 is a schematic diagram of connection between a driving mechanism, a sliding mechanism, and a clamping jaw unit according to an embodiment of the present disclosure.

Description of reference numerals: 1. main controller; 10. magazine body; 11. opening; 20. clamping jaw unit; 21. first plate member; 22. second plate member; 23. third plate member; 30. snap-fit structure; 40. notch; 50. sliding rail; 51. sliding stage; 60. driving mechanism; 70. second sensing mechanism; 80. housing; 81. upper top plate; 82. lower bottom plate; 83. side plate; 84. rear plate; 85. front plate; 86. partition plate; 90. shielding mechanism; 91. moving rod member; 92. shielding member; 93. movable connecting member; 100. top plate; 101. lifting member; 110. blocking sheet; 120. first sensing mechanism; 200. protruding structure; 201. pressing structure; 202. transmission structure; 203. microswitch; 700. second optical signal transmitter; 710. second optical signal receiver; 800. mounting opening; 810. accommodating cavity; 850. signal port; 1010. recessed structure; 1200. first optical signal transmitter; 1210.first optical signal receiver; 2000. main body.

### DETAILED DESCRIPTION OF THE EMBODIMENTS

Some embodiments of the present disclosure will be described below with reference to the accompanying drawings. It should be understood by those skilled in the art that these embodiments are only used to explain the technical principles of the present disclosure and are not intended to limit the protection scope of the present disclosure.

As described in the background art, in the processing stages, a clamping jaw is often used to grip a magazine, and the clamping jaw is driven by a manipulator to transport the magazine to a designated position. The magazine is provided with openings at two ends; the IC chip is placed inside the magazine through the openings; the clamping jaw directly clamps two side walls of the magazine that are not provided with the openings. When the clamping force of the clamping jaws is not properly controlled, if the clamping force is too large, physical damage may be caused to the metal surface of the magazine; if the clamping force is too small, the magazine may not be firmly clamped, resulting in a shift in the center of gravity and thus deflection of the magazine. As a result, the IC chip may slide out from the opening, and in severe cases, the magazine directly falls off, resulting in damage to both the magazine and the IC chip.

The present disclosure provides a clamping jaw apparatus, aiming to firmly clamp a magazine body.

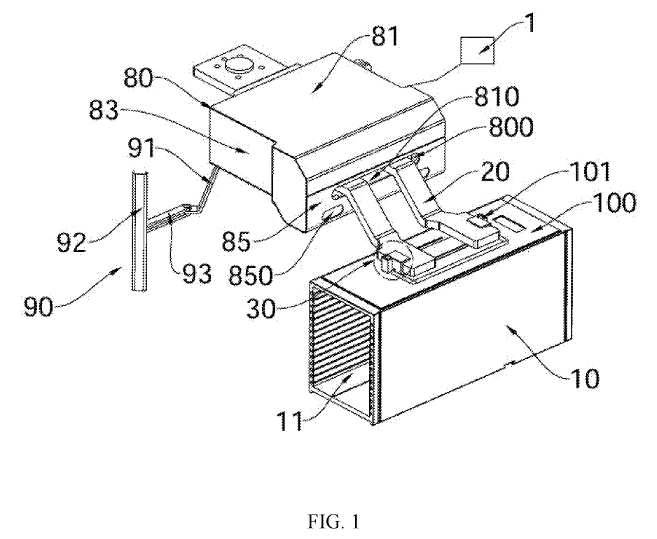

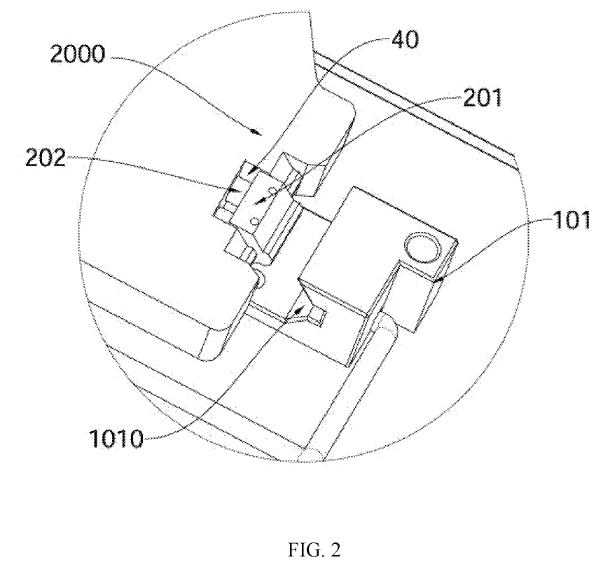

Referring to an overall schematic diagram of a clamping jaw apparatus shown in FIG. 1 and a schematic diagram of a protruding structure and a recessed structure shown in FIG. 2, provided is a clamping jaw apparatus for clamping a magazine body 10. The magazine body 10 includes a top plate 100 provided with at least two lifting members 101, and the lifting member 101 includes a recessed structure 1010; the clamping jaw apparatus includes at least two clamping jaw units 20, and the clamping jaw unit 20 includes a protruding structure 200; the protruding structure 200 cooperates with the recessed structure 1010. The clamping jaw unit 20 moves in a direction proximal to the lifting member 101, so that the protruding structure 200 and the recessed structure 1010 engage and abut to form a snap-fit structure 30, or moves in a direction distal to the lifting member 101, so that the protruding structure 200 and the recessed structure 1010 are separated to disconnect the snap-fit structure 30.

The protruding structure 200 on the clamping jaw unit 20 and the recessed structure 1010 of the lifting member 101 on the top plate 100 of the magazine body are designed to complement and cooperate with each other, and thus the two are snap-fitted to form the snap-fit structure 30, realizing the stable clamping of the magazine body 10, thereby protecting an object in the magazine body 10 from damage during transportation while avoiding the problem that the magazine body 10 is damaged or the object slides out from the magazine body 10 due to an improper clamping force.

In some embodiments of the present disclosure, two lifting members 101 are provided, a preset distance is maintained therebetween, and the recessed structures 1010 thereof are disposed opposite to each other; two clamping jaw units 20 are provided, the clamping jaw units are located between the two lifting members 101 in an initial state, and the protruding structure 200 faces the recessed structure 1010. When a clamping operation is performed, the two clamping jaw units 20 are separated from each other and move toward the lifting members 101 on their corresponding sides, respectively, so that the protruding structure 200 and the recessed structure 1010 on one side engage and lock together to form the snap-fit structure 30. Through cooperation between the protruding structure 200 and the recessed structure 1010, the clamping jaw units 20 can firmly clamp the magazine body 10, thereby reducing the risk of the object sliding out or the magazine body 10 being damaged due to unstable clamping during transportation. In addition, the clamping jaw units 20 consider a balanced distribution of forces, and through the symmetrical operation of the two clamping jaw units 20, an even distribution of forces during clamping is ensured, thereby avoiding the inclination of the object or the deformation of the magazine body 10 caused by uneven forces.

In some embodiments of the present disclosure, the clamping jaw apparatus can adapt to magazine bodies 10 of different dimensions and shapes. As long as the top plate 100 of the magazine body 10 is provided with a corresponding lifting member 101 and a corresponding recessed structure 1010; in this case, a clamping operation can be quickly performed through the clamping jaw unit 20 to realize stable clamping, thereby improving the operation efficiency and reducing the complexity of manual operation.

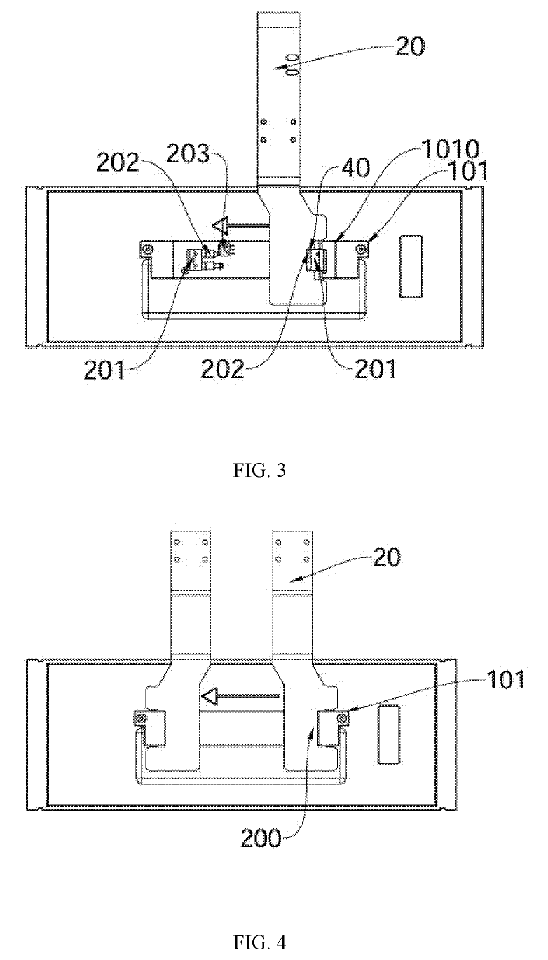

Preferably, referring to a schematic diagram of a protruding structure and a recessed structure shown in FIG. 2 and schematic diagrams of a first state and a second state shown in FIGS. 3 and 4, the clamping jaw apparatus further includes a main controller 1. The protruding structure 200 includes a main body 2000, a pressing structure 201, and a transmission structure 202 and a microswitch 203 that are disposed inside the main body 2000. A notch 40 is formed in one side of the main body 2000, the pressing structure 201 and the notch 40 complement each other, and the pressing structure 201 is connected to the transmission structure 202. In the first state, the pressing structure 201 moves from the notch 40 to a pressing position in a direction distal to the main body 2000, and the pressing position is located on one side of the recessed structure 1010. In the second state, the protruding structure 200 moves toward the recessed structure 1010, so that the pressing structure 201 abuts against the recessed structure 1010; the pressing structure 201 moves to the notch 40 in a direction proximal to the main body 2000 and cooperates with the notch 40 to form a whole, so that the protruding structure 200 and the recessed structure 1010 engage and abut to form the snap-fit structure 30. When the pressing structure 201 and the notch 40 cooperate to form a whole, the pressing structure 201 applies an external force onto the microswitch 203 through the transmission structure 202, and the microswitch 203 transmits a locking signal to the main controller 1 after being triggered, where the locking signal is used for indicating that the clamping jaw apparatus and the magazine body 10 are clamped.

In the first state, i.e., the initial state, the pressing structure 201 is not embedded in the main body 2000 and naturally extends outside the main body 2000. In the second state, i.e., under the clamping action, the pressing structure 201 first engages and contacts the recessed structure 1010 and is then pushed back into the notch 40 under the action of an external force to complement the notch 40 to form a whole; then the protruding structure 200 and the recessed structure 1010 engage and abut to form the snap-fit structure 30, so that the clamping jaw unit 20 and the lifting member 101 are firmly clamped, thereby improving the stability of the clamping jaw apparatus.

In some embodiments of the present disclosure, when the protruding structure 200 is separated from the recessed structure 1010, the pressing structure 201 is separated from the notch 40, protrudes from the notch 40 in a direction distal to the main body 2000, and is reset to a position in the first state, i.e., the initial state.

In some embodiments of the present disclosure, in the first state, a certain distance is maintained between one end of the transmission structure 202 distal to the pressing structure 201 and the microswitch 203. When the pressing structure 201 and the notch 40 complement each other to form a whole, the transmission structure 202 touches the microswitch 203, generating the locking signal.

Preferably, referring to a schematic diagram of connection between a driving mechanism, a sliding mechanism, and a clamping jaw unit shown in FIG. 6, the clamping jaw apparatus further includes a sliding mechanism, and the sliding mechanism includes a sliding rail 50 and a sliding stage 51 disposed on the sliding rail 50. The clamping jaw unit 20 is connected to the sliding stage 51 and moves on the sliding rail 50 through the sliding stage 51 in the direction proximal to the lifting member 101 or the direction distal to the lifting member 101.

The arrangement of the sliding mechanism enables the two clamping jaw units 20 to move proximal to or distal to each other, so that the protruding structure 200 and the recessed structure 1010 engage to form the snap-fit structure 30, or the protruding structure 200 and the recessed structure 1010 are separated and disconnected, thereby improving the operation flexibility.

In some embodiments of the present disclosure, the sliding rail 50 adopts a linear ball-type guide sliding rail with a straightness of up to 1 μm, so as to realize high-precision sliding.

In some embodiments of the present disclosure, the sliding mechanism may be disposed above or below the clamping jaw unit 20.

In some embodiments of the present disclosure, the sliding mechanism can realize long-stroke sliding through a chain structure, so that the clamping jaw unit 20 can move over a relatively large distance to adapt to a larger operation range.

Preferably, referring to a schematic diagram of connection between a driving mechanism, a sliding mechanism, and the clamping jaw unit shown in FIG. 6, the clamping jaw apparatus further includes a driving mechanism 60. The driving mechanism 60 is connected to one end of the clamping jaw unit 20 distal to the protruding structure 200, so as to drive the clamping jaw unit 20 to move on the sliding rail 50 through the sliding stage 51.

The arrangement of the driving mechanism 60 provides power for the movement of the clamping jaw unit 20, so that the clamping jaw unit moves on the sliding rail 50.

In some embodiments of the present disclosure, the driving mechanism 60 adopts a servo motor to provide precise speed and position control.

In some embodiments of the present disclosure, the driving mechanism 60 adopts a stepper motor to provide an accurate stepping speed for precisely controlling the opening and closing positions of the clamping jaw unit 20.

In some embodiments of the present disclosure, the driving mechanism 60 adopts a hydraulic cylinder or a pneumatic cylinder, and opens and closes the jaws through the transmission of a rack and pinion mechanism, so as to realize the approach or separation of the clamping jaw units 20.

Preferably, the clamping jaw apparatus further includes a blocking sheet 110 and at least one first sensing mechanism 120. The first sensing mechanism 120 is disposed below the clamping jaw unit 20 in a height direction and includes a first optical signal transmitter 1200and a first optical signal receiver 1210; the first optical signal transmitter 1200 is configured to transmit an optical signal, and the first optical signal receiver 1210 is configured to receive the optical signal. The blocking sheet 110 is disposed at the bottom of the clamping jaw unit 20 in the height direction, and when the protruding structure 200 and the recessed structure 1010 engage and abut to form the snap-fit structure 30, the blocking sheet 110 is located between the first optical signal transmitter 1200 and the first optical signal receiver 1210 to block the optical signal. The first sensing mechanism 120 transmits a termination signal to the main controller 1, and the main controller 1 controls the driving mechanism 60 to stop operation based on the termination signal.

When the protruding structure 200 and the recessed structure 1010 engage to form the snap-fit structure 30, the clamping jaw unit 20 is clamped with the lifting member 101, while the driving mechanism 60 still does not stop operation and still drives the clamping jaw unit 20 to move in a direction toward the lifting member 101. As a result, in a clamped state, the clamping jaw unit 20 continuously presses against the lifting member 101, which easily causes damage to the clamping jaw unit 20 and the lifting member 101. Therefore, the blocking sheet 110 is used to cut off the optical signal path of the first sensing mechanism 120, and the first sensing mechanism 120 transmits the termination signal to the main controller 1 to stop the operation of the driving mechanism, thereby avoiding damage to the clamping jaw unit and the lifting member 101 caused by the continuous movement of the clamping jaw unit 20.

In some embodiments of the present disclosure, the first sensing mechanism 120 adopts an optical signal sensor.

In some embodiments of the present disclosure, the blocking sheet 110 is of a sheet-like cuboid structure. When the blocking sheet 110 passes through the optical signal path, the optical signal path is perpendicular to the blocking sheet 110.

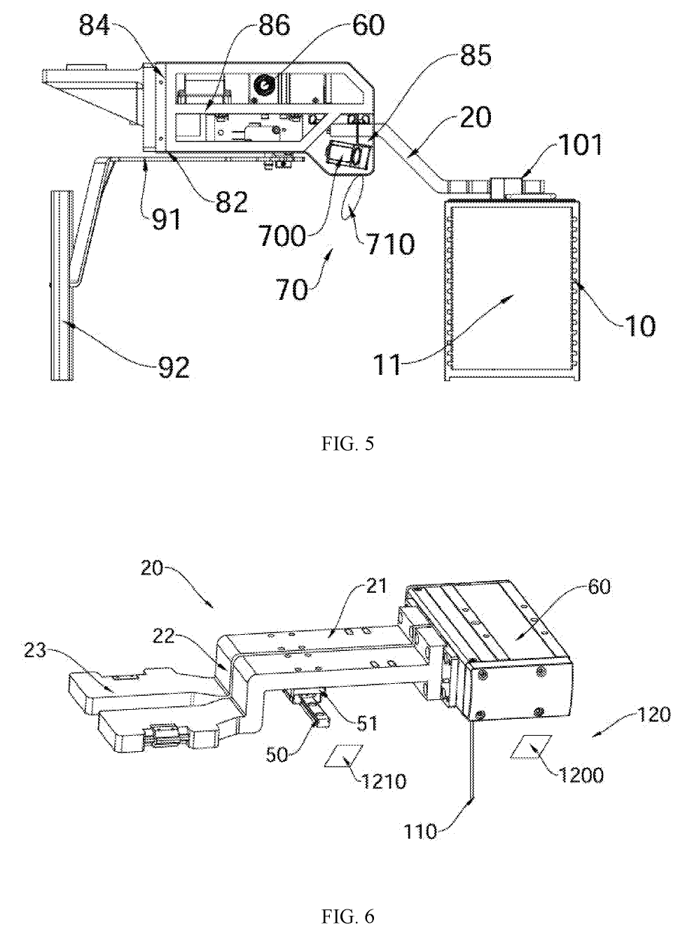

Preferably, referring to a schematic side sectional diagram of an interior of a housing shown in FIG. 5, the clamping jaw apparatus further includes at least two second sensing mechanisms 70. The second sensing mechanism 70 is disposed proximal to the clamping jaw unit 20 and includes a second optical signal transmitter 700 and a second optical signal receiver 710. The second optical signal transmitter 700 is configured to transmit a detection signal in a direction toward the lifting member 101, and the second optical signal receiver is configured to receive a reflected signal formed after the detection signal is incident on the lifting member. The second sensing mechanism 70 transmits the reflected signal to the main controller 1; the main controller 1 determines whether an included angle between a transmission path of the detection signal and a plane on which the lifting member 101 is located maintains a preset angle based on the reflected signal; if so, it is determined that the relative positions of the lifting member 101 and the clamping jaw unit 20 meet a preset standard, and the clamping jaw unit 20 is controlled to move in the direction proximal to the lifting member 101.

The second sensing mechanism is configured to detect whether the magazine body 10 is located at a correct position. If the magazine body is not located at the correct position, the clamping jaw unit 20 cannot be clamped with the lifting member 101. In this case, only when the relative positions of the lifting member 101 and the clamping jaw unit 20 meet the preset standard, the main controller 1 controls the clamping jaw unit 20 to move in the direction proximal to the lifting member 101 to be clamped with the lifting member 101.

In some embodiments of the present disclosure, the second sensing mechanism adopts an optical signal sensor.

Preferably, referring to an overall schematic diagram of a clamping jaw apparatus shown in FIG. 1 and a schematic side sectional diagram of an interior of a housing shown in FIG. 5, the clamping jaw apparatus further includes a housing 80. The housing 80 includes an accommodating cavity 810 and a mounting opening 800; the driving mechanism 60 is disposed on one side of the accommodating cavity 810 distal to the mounting opening 800, the sliding mechanism is disposed on one side of the accommodating cavity 810 proximal to the mounting opening 800, a part of the clamping jaw unit 20 connected to the driving mechanism 60 and the sliding mechanism is located in the accommodating cavity 810, and the other part of the clamping jaw unit passes through the mounting opening 800 in a direction distal to the accommodating cavity 810 and extends outside the housing 80.

The arrangement of the housing 80 provides a mounting space for the driving mechanism 60 and the sliding mechanism, which protects the safety of the mechanism and avoids damage to the internal mechanism caused by the collision between the clamping jaw apparatus and the outside when the clamping jaw apparatus performs a gripping action.

In some embodiments of the present disclosure, the housing 80 includes an upper top plate 81, a lower bottom plate 82, side plates 83, a rear plate 84, and a front plate 85. Several plate members define the housing 80 in an enclosing manner, the accommodating cavity 810 is formed inside the housing 80, and a partition plate 86 is provided in the accommodating cavity 810 to divide the accommodating cavity 810 into an upper part and a lower part. The driving mechanism 60 is mounted below the upper top plate 81 and above the partition plate 86. The sliding rail mechanism is located below the partition plate 86 and disposed proximal to the front plate 85. The first sensing mechanism 120 is disposed proximal to the sliding rail mechanism, and the second sensing mechanism is located below the sliding rail mechanism and disposed proximal to the front plate 85. The detection signal transmitted by the second sensing mechanism passes through a signal port 850 on the front plate 85 to the lifting member 101.

Preferably, referring to a schematic diagram of connection between a driving mechanism, a sliding mechanism, and a clamping jaw unit shown in FIG. 6, the clamping jaw unit 20 includes a first plate member 21, a second plate member 22, and a third plate member 23, which are connected sequentially to form an approximately “Z”-shaped structure. The first plate member 21 is connected to the drive end of the driving mechanism 60, and the bottom end of the first plate member 21 is connected to the sliding stage 51; one end of the second plate member 22 is connected to one end of the first plate member 21 distal to the drive end, and the other end of the second plate member passes through the mounting opening 800 in a direction distal to the accommodating cavity 810 and extends outside the housing 80 to be connected to the third plate member 23; one end of the third plate member 23 distal to the second plate member 22 is provided with the protruding structure 200.

The clamping jaw unit 20 is designed to be of a “Z”-shaped structure; the first plate member 21 and the third plate member 23 are disposed in parallel, which is convenient for the driving mechanism 60 to drive the clamping jaw unit 20 to move, thereby optimizing the movement path of the clamping jaw unit 20. The arrangement of the second plate member 22 adapts to a drop between the clamping jaw apparatus and the magazine body 10, thereby improving the adaptability of the clamping jaw apparatus.

In some embodiments of the present disclosure, both ends of the second plate member 22 are perpendicular to the first plate member 21 and the third plate member 23, respectively.

In some embodiments of the present disclosure, a junction between one end of the second plate member 22 and the first plate member 21 is maintained at a preset angle, and a junction between the other end of the second plate member and the third plate member 23 is maintained at a preset angle.

Preferably, referring to an overall schematic diagram of a clamping jaw apparatus shown in FIG. 1 and a schematic side sectional diagram of an interior of a housing shown in FIG. 5, the magazine body 10 includes at least one opening 11, and an object is placed in the magazine body 10 through the opening 11. The clamping jaw apparatus further includes at least one shielding mechanism 90, and the shielding mechanism 90 is disposed on the outer side wall of the housing 80. When the protruding structure 200 and the recessed structure 1010 engage and abut, the shielding mechanism 90 moves to the opening 11 to abut against the end surface of the magazine body 10 that is provided with the opening 11, so as to prevent the object from falling off the magazine body 10 through the opening 11.

When the clamping jaw apparatus clamps the magazine body 10, due to the existence of the opening 11 of the magazine body 10, if the magazine body 10 is interfered with an external acting force, the magazine body may shake and vibrate, causing the object in the magazine body 10 to fall out from the opening 11. In this case, the shielding mechanism 90 blocks the opening 11 side of the magazine body 10 and is in close contact with the magazine body 10 structure, which can prevent the object from falling out through the opening 11 and thus ensure the safety of the object stored in the magazine body 10.

Preferably, the shielding mechanism 90 includes a moving rod member 91, a shielding member 92, and a movable connecting member 93. One end of the moving rod member 91 is connected to the housing 80, and the other end of the moving rod member is connected to the shielding member 92 through the movable connecting member 93. The movable connecting member 93 is configured to alleviate a reaction force applied by the magazine body 10 onto the shielding member 92 when the shielding member 92 abuts against the magazine body. When the shape of the magazine body 10 conforms to a preset shape, the shielding member 92 abuts against the end surface of the magazine body 10 that is provided with the opening 11, the movable connecting member 93 is in a natural state, and a first preset angle is maintained between the moving rod member 91 and the shielding member 92. When the shape of the magazine body 10 does not conform to the preset shape, the shielding member 92 abuts against the end surface of the magazine body 10 that is provided with the opening 11, the movable connecting member 93 is in an expanded state, and a second preset angle is maintained between the moving rod member 91 and the shielding member 92. The second preset angle is greater than the first preset angle.

Different types of magazine bodies 10 have different sizes. For the magazine body 10 with smaller dimensions and conforming to the preset shape, the shielding member 92 can just abut against the end surface of the magazine body 10 that is provided with the opening 11 when moving to the opening 11. For the magazine body 10 with slightly larger dimensions and not conforming to the preset shape, the shielding member 92 is forced open by the end surface of the magazine body 10 that is provided with the opening 11 when moving to the opening 11, and the movable connecting member 93 is in an expanded state, so as to alleviate the reaction force applied by the magazine body 10 onto the shielding member 92 when the shielding member 92 abuts against the magazine body, thereby avoiding damage to the shielding member 92. This design is applicable to a plurality of types of magazine bodies 10 and enhances the adaptability and practicability of the clamping jaw apparatus.

In some embodiments of the present disclosure, when the second sensing mechanism detects that the relative positions of the clamping jaw unit 20 and the magazine body 10 meet the preset standard, the main controller 1 controls the clamping jaw unit 20 to move toward the lifting member 101 of the magazine body 10, so that the protruding structure 200 and the recessed structure 1010 engage and are clamped to form the snap-fit structure 30. In addition, the blocking sheet 110 below the clamping jaw unit 20 cuts off the optical signal path of the first sensing mechanism 120. The main controller 1 controls the driving mechanism 60 to stop operation and controls the shielding mechanism 90 to move toward the opening 11 of the magazine body 10, so that the shielding mechanism 90 abuts against the end surface structure of the magazine body 10 that is provided with the opening 11.

In the description of the specification, the description of reference terms “one embodiment”, “some embodiments”, “an example”, “a specific example”, or “some examples” and the like means that specific features, structures, materials, or characteristics described in connection with the embodiments or examples are included in at least one embodiment or example of the present disclosure. In this specification, the schematic description of the above terms does not necessarily refer to the same embodiment or example. Moreover, the specific features, structures, materials, or characteristics described may be combined in a suitable manner in any one or more embodiments or examples.

In addition, the terms “first” and “second” are used herein for descriptive purposes only and should not be construed as indicating or implying relative importance or implicitly indicating the quantity of technical features described. Thus, a feature defined by “first” or “second” may explicitly or implicitly include at least one such feature. In the description of the present disclosure, “plurality” means at least two, e.g., two or three, unless otherwise explicitly and specifically defined.

Although the embodiments of the present disclosure have been shown and described above, it will be understood that the above embodiments are exemplary and not to be construed as limiting the present disclosure. Those of ordinary skill in the art can make changes, modifications, substitutions, and variations to the above embodiments within the scope of the present disclosure.

What is claimed is:

1. A clamping jaw apparatus for clamping a magazine body, wherein the magazine body comprises a top plate provided with at least two lifting members, and the lifting member comprises a recessed structure; the clamping jaw apparatus comprises:
at least two clamping jaw units, wherein the clamping jaw unit comprises a protruding structure, and the protruding structure cooperates with the recessed structure;
the clamping jaw unit moves in a direction proximal to the lifting member, so that the protruding structure and the recessed structure engage and abut to form a snap-fit structure, or moves in a direction distal to the lifting member, so that the protruding structure and the recessed structure are separated to disconnect the snap-fit structure.

2. The clamping jaw apparatus according to claim 1, further comprising a main controller, wherein
the protruding structure comprises a main body, a pressing structure, and a transmission structure and a microswitch that are disposed inside the main body, a notch is formed in one side of the main body, the pressing structure cooperates with the notch, and the pressing structure is connected to the transmission structure;
in a first state, the pressing structure moves from the notch to a pressing position in a direction distal to the main body, and the pressing position is located on one side of the recessed structure;
in a second state, the protruding structure moves toward the recessed structure, so that the pressing structure abuts against the recessed structure; the pressing structure moves to the notch in a direction proximal to the main body and cooperates with the notch to form a whole, so that the protruding structure and the recessed structure engage and abut to form the snap-fit structure,
wherein when the pressing structure cooperates with the notch to form a whole, the pressing structure applies an external force onto the microswitch through the transmission structure, and the microswitch transmits a locking signal to the main controller after being triggered, the locking signal being used for indicating that the clamping jaw apparatus and the magazine body are clamped.

3. The clamping jaw apparatus according to claim 2, further comprising a sliding mechanism, wherein the sliding mechanism comprises a sliding rail and a sliding stage disposed on the sliding rail;
the clamping jaw unit is connected to the sliding stage and moves on the sliding rail through the sliding stage in the direction proximal to the lifting member or the direction distal to the lifting member.

4. The clamping jaw apparatus according to claim 3, further comprising a driving mechanism, wherein the driving mechanism is connected to one end of the clamping jaw unit distal to the protruding structure, so as to drive the clamping jaw unit to move on the sliding rail through the sliding stage.

5. The clamping jaw apparatus according to claim 4, further comprising a blocking sheet and at least one first sensing mechanism, wherein
the first sensing mechanism is disposed below the clamping jaw unit in a height direction and comprises a first optical signal transmitter and a first optical signal receiver, the first optical signal transmitter is configured to transmit an optical signal, and the first optical signal receiver is configured to receive the optical signal;
the blocking sheet is disposed at a bottom of the clamping jaw unit in the height direction, and when the protruding structure and the recessed structure engage and abut to form the snap-fit structure, the blocking sheet is located between the first optical signal transmitter and the first optical signal receiver to block the optical signal; the first sensing mechanism transmits a termination signal to the main controller, and the main controller controls the driving mechanism to stop operation based on the termination signal.

6. The clamping jaw apparatus according to claim 4, further comprising at least two second sensing mechanisms, wherein the second sensing mechanism is disposed proximal to the clamping jaw unit and comprises a second optical signal transmitter and a second optical signal receiver, the second optical signal transmitter is configured to transmit a detection signal in a direction toward the lifting member, and the second optical signal receiver is configured to receive a reflected signal formed after the detection signal is incident on the lifting member;
the second sensing mechanism transmits the reflected signal to the main controller, and the main controller determines whether an included angle between a transmission path of the detection signal and a plane on which the lifting member is located maintains a preset angle based on the reflected signal;
if so, it is determined that relative positions of the lifting member and the clamping jaw unit meet a preset standard, and the clamping jaw unit is controlled to move in the direction proximal to the lifting member.

7. The clamping jaw apparatus according to claim 4, further comprising a housing, wherein the housing comprises an accommodating cavity and a mounting opening, the driving mechanism is disposed on one side of the accommodating cavity distal to the mounting opening, the sliding mechanism is disposed on one side of the accommodating cavity proximal to the mounting opening, a part of the clamping jaw unit connected to the driving mechanism and the sliding mechanism is located in the accommodating cavity, and the other part of the clamping jaw unit passes through the mounting opening in a direction distal to the accommodating cavity and extends outside the housing.

8. The clamping jaw apparatus according to claim 7, wherein the clamping jaw unit comprises a first plate member, a second plate member, and a third plate member connected sequentially, the first plate member is connected to a drive end of the driving mechanism, a bottom end of the first plate member is connected to the sliding stage, one end of the second plate member is connected to one end of the first plate member distal to the drive end, the other end of the second plate member passes through the mounting opening in a direction distal to the accommodating cavity and extends outside the housing to be connected to the third plate member, and one end of the third plate member distal to the second plate member is provided with the protruding structure.

9. The clamping jaw apparatus according to claim 7, wherein the magazine body comprises at least one opening, and an object is placed in the magazine body through the opening;
the clamping jaw apparatus further comprises at least one shielding mechanism, the shielding mechanism is disposed on an outer side wall of the housing, and when the protruding structure and the recessed structure engage and abut, the shielding mechanism moves to the opening to abut against an end surface of the magazine body that is provided with the opening, so as to prevent the object from falling off the magazine body through the opening.

10. The clamping jaw apparatus according to claim 9, wherein the shielding mechanism comprises a moving rod member, a shielding member, and a movable connecting member, one end of the moving rod member is connected to the housing, and the other end of the moving rod member is connected to the shielding member through the movable connecting member;
the shielding member abuts against the end surface of the magazine body that is provided with the opening, and the movable connecting member is configured to alleviate a reaction force applied by the magazine body onto the shielding member when the shielding member abuts against the magazine body.
